(19) United States
(12) Patent Application Publication
(10) Pub. No.: US 2025/0253122 A1
(43) Pub. Date: Aug. 7, 2025

(54) MEASUREMENT DEVICE AND SCANNING IMAGE ACQUISITION METHOD

(71) Applicant: Hitachi High- Tech Corporation, Tokyo (JP)

(72) Inventors: Keiichiro HITOMI, Tokyo (JP); Akihiro MIURA, Tokyo (JP); Naoya NAKAI, Tokyo (JP); Ryuji SATO, Tokyo (JP)

(21) Appl. No.: 18/947,743

(22) Filed: Nov. 14, 2024

(30) Foreign Application Priority Data
Feb. 7, 2024 (JP) 2024-016930

(51) Int. Cl. H01J 37/22; H01J 37/244; H01J 37/26; H01J 37/28

(52) U.S. Cl. CPC H01J 37/222; H01J 37/226; H01J 37/244; H01J 37/265; H01J 37/28; H01J 2237/24495; H01J 2237/24592; H01J 2237/2817

(57) ABSTRACT

The invention enables highly accurate dimension measurement while reducing a side effect caused by laser light irradiation.

A measurement device for measuring a dimension of a predetermined pattern on a wafer at a plurality of measurement points, includes: an imaging unit 101 including a charged particle optical system and a detector 108; an image processing unit 111 configured to create a scanning image in response to a detection signal from the detector; an irradiation optical system 120 including a laser light source 121 and a shutter 122 configured to control irradiation toward the region with light from the laser light source; and a controller 112 configured to control the imaging unit and the irradiation optical system. The controller performs time adjustment such that an irradiation amount of light from the laser light source from when the shutter is opened to start the irradiation with the light from the laser light source to when the imaging unit starts imaging of the scanning image is equal at the plurality of measurement points.

### CROSS-REFERENCE TO RELATED APPLICATION

This application claims priority to Japanese Patent Application No. 2024-016930 filed on Feb. 7, 2024, the entire contents of which are incorporated by reference herein.

### TECHNICAL FIELD

The present invention relates to a measurement device and a scanning image acquisition method of the measurement device.

### BACKGROUND ART

In a semiconductor device manufacturing line, a shape of a pattern formed on a semiconductor wafer is measured by a measurement device provided in the manufacturing line, and quality of the pattern is monitored to improve a yield. Along with miniaturization and three-dimensionalization of a semiconductor device, high accuracy in length measurement is required, and improvement in throughput is also strongly required in the measurement device in order to cope with mass production. However, the accuracy of length measurement and the throughput are in a tread-off relationship.

PTL 1 discloses an inspection device that irradiates a wafer with a laser beam to inspect a position and a type of a defect on the wafer.

### CITATION LIST

### Patent Literature

PTL 1: JP2003-151483A

### SUMMARY OF INVENTION

### Technical Problem

An example of a factor that lowers measurement accuracy is sample charging. Examples of an adverse effect caused by the sample charging include disappearance of a pattern edge. Since a large amount of secondary electrons are emitted from a pattern edge portion, strong positive charging occurs in a sample. Since signal electrons emitted from the pattern edge portion are positively charged and returned to a sample side, the signal electrons from the pattern edge portion detected by a detector become small, and the pattern edge cannot be identified from a scanning image.

In the related art, efforts are made to increase a scanning speed of the electron beam in order to reduce the sample charging, but the charging cannot be removed fundamentally. In response to this, as disclosed in PTL 1, the sample charging can be removed by laser irradiation.

However, when the sample is irradiated with laser light, a change in a pattern shape occurs due to damage or contamination to the sample. Since an amount of the change in the pattern shape depends on a laser light irradiation amount, control of the amount of laser light irradiation is required for highly accurate pattern dimension variation management.

### Solution to Problem

A measurement device according to an aspect of an embodiment of the invention, which measures a dimension of a predetermined pattern on a wafer at a plurality of measurement points, includes: an imaging unit including a charged particle optical system, a stage, and a detector configured to detect signal electrons emitted when the wafer placed on the stage is irradiated with a charged particle beam from the charged particle optical system; an image processing unit configured to generate a scanning image in response to a detection signal output by the detector after the charged particle optical system scans the wafer with the charged particle beam and the detector detects the signal electrons; an irradiation optical system including a laser light source, an optical element configured to irradiate a region including a field of view of the charged particle optical system with light from the laser light source, and a shutter configured to control irradiation of the region with the light from the laser light source; and a controller configured to control the imaging unit and the irradiation optical system. The controller performs time adjustment such that an irradiation amount of light from the laser light source from when the shutter is opened to start the irradiation with the light from the laser light source to when the imaging unit starts imaging of the scanning image is equal at the plurality of measurement points.

### Advantageous Effects of Invention

The invention enables highly accurate dimension measurement while reducing a side effect caused by laser light irradiation. Other problems and novel features will become apparent from description of the present specification and the accompanying drawings.

### BRIEF DESCRIPTION OF DRAWINGS

FIG. 1 is a schematic configuration diagram of a charged particle beam device.

FIG. 2 is a hardware structure example of an information processing device.

FIG. 3 is a diagram schematically showing a wafer as a sample.

FIG. 4 is a flowchart of a method for acquiring an SEM image used for measuring a pattern.

FIG. 5 is a time chart (schematic diagram) for acquiring the SEM image.

FIG. 6 is an example of an alarm screen.

FIG. 7 is a display example of measurement result data.

FIG. 8 is a flowchart of a method for creating a measurement recipe.

FIG. 9 is an example of a checking screen.

FIG. 10 is a data configuration example of a processing method database.

FIG. 11 is an example of a selection screen.

### DESCRIPTION OF EMBODIMENTS

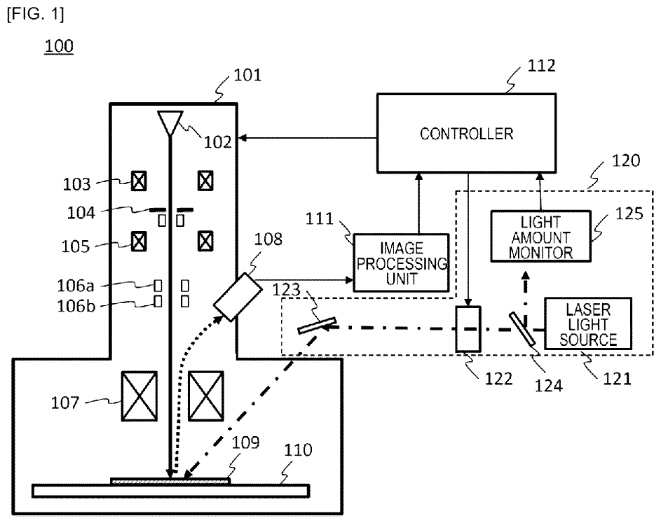

FIG. 1 is a schematic configuration diagram of a charged particle beam device used as a measurement device. Here, an example of the charged particle beam device is a scanning electron microscope (SEM) 100 that scans a sample with an electron beam to acquire an electron beam image. The SEM 100 measures a length of a predetermined portion (referred to as a measurement point) of a pattern formed on the sample based on the acquired electron beam image (SEM image), and monitors quality of the formed pattern. In the SEM 100, a measurement recipe for measuring the measurement point on the sample is set in a controller in advance, and the SEM 100 functions as a measurement device by acquiring a scanning image of the sample according to the set measurement recipe and measuring the length of the measurement point.

The SEM 100 includes, as a main configuration, an imaging unit 101, a controller 112, and an irradiation optical system 120 that emits laser light for controlling sample charging.

The imaging unit 101 includes, as a main configuration, an electron optical system, a stage 110 on which the sample is placed, and a detector 108 that detects signal electrons emitted when the sample is irradiated with an electron beam from the electron optical system. The electron optical system includes an electron source 102, focusing lenses 103 and 105 for controlling a probe diameter and a probe current amount of an electron beam emitted from the electron source 102 toward a sample 109 placed on the stage 110, a diaphragm 104, an image shift deflector 106a for controlling an irradiation position of the electron beam on the sample 109, a scanning deflector 106b for scanning the electron beam on the sample 109, and an objective lens 107 for focusing the electron beam on the sample 109. These components are provided in a housing, and an inside of the housing through which the electron beam passes is in a vacuum environment. An image processing unit 111 receives a detection signal output by the detector 108 after detecting the signal electrons, and creates an SEM image (scanning image).

The irradiation optical system 120 controls charging of the sample 109 by irradiating the sample 109 with light. Here, the irradiation optical system 120 is provided in an atmospheric environment, and the light from the irradiation optical system 120 is emitted onto the sample 109 through a window (not shown) provided in the imaging unit 101. The irradiation optical system 120 includes optical elements such as a laser light source 121, a shutter 122 for controlling ON/OFF of light from the laser light source 121, and a mirror 123 for guiding the light to a region including a field of view of the electron optical system in the sample 109. By using the laser light source 121 as the light source of the light with which the sample 109 is irradiated, it is possible to irradiate the sample 109 with light of a wavelength aligned according to a material of the sample 109 to be subjected to charge control, for example, ultraviolet light of a specific wavelength, and it is possible to efficiently perform the charge control. Further, a part of the light from the laser light source 121 is introduced into a light amount monitor 125 through a half mirror 124, and the light amount output from the laser light source 121 is monitored. For example, the light amount monitor 125 receives the light from the laser light source 121 and measures power thereof.

The shutter 122 is controlled by the controller 112, and a value of the light amount (power) output from the laser light source 121 measured by the light amount monitor 125 is transmitted to the controller 112.

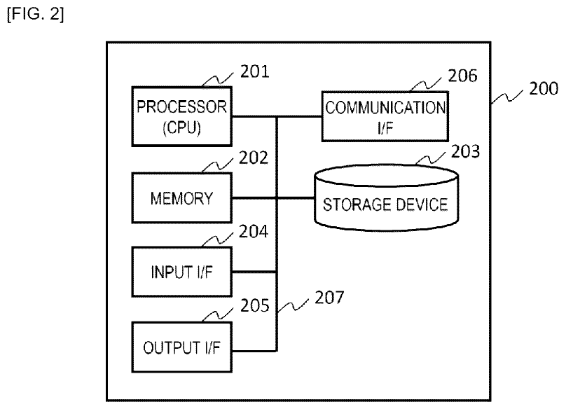

The controller 112 is implemented by an information processing device (computer) 200 including a processor (central processing unit: CPU) 201, a memory 202, a storage device 203, an input interface (I/F) 204, an output I/F 205, a communication I/F 206, and a bus 207, as shown in FIG. 2. The processor 201 functions as a functional unit that provides a predetermined function by executing processing according to a program loaded in the memory 202. The storage device 203 stores data and a program used by the functional unit. The input I/F 204 is connected to an input device such as a keyboard, a pointing device, or an operation panel, and the output I/F 205 is connected to a display device. The communication device I/F 206 enables communication with another information processing device via a network. These components are communicably connected to one another via a bus 207.

For the sake of description, in the case of describing processing executed by a program, a program, a function, a processing unit, and the like may be described as a main body, but a main body of hardware thereof is a processor, or an information processing device (computer) that includes the processor or the like. The information processing device executes processing according to a program read onto a memory by a processor while appropriately using resources such as a memory and a communication interface. Although FIG. 2 shows an example of a CPU as a processor, a graphical processing unit (GPU) or the like may also be used. Processing for implementing a function is not limited to software program processing, and can be implemented by a dedicated circuit. For example, a field-programmable gate array (FPGA) or an application specific integrated circuit (ASIC) may be used.

### Embodiment 1

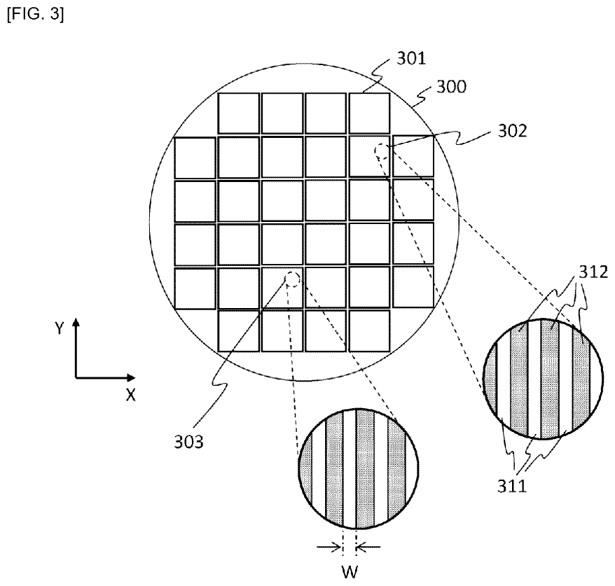

FIG. 3 schematically shows a wafer 300 as an example of the sample 109. The wafer 300 includes a plurality of chip regions 301. In each of the plurality of chip regions 301, a semiconductor layer, an insulator layer, a conductive layer, or the like of a predetermined pattern is stacked, and finally, a resultant is separated by dicing to obtain a large number of semiconductor chips. Here, a pattern to be measured is a line-and-space (L/S) pattern. For example, it is assumed that the L/S pattern is formed in which resists 311 are formed on conductive layers 312 serving as an undercoat, and a width W of the resist 311 is to be measured. In this case, since the L/S pattern to be measured is included in the same chip region or another chip region in the wafer 300, measurement points 302 and 303 including the L/S pattern are set to acquire the SEM image. Although two measurement points are shown here, a large number of measurement points are actually set on the wafer. The pattern to be measured is not limited to the L/S pattern, and may be a pattern or a via having a specific shape.

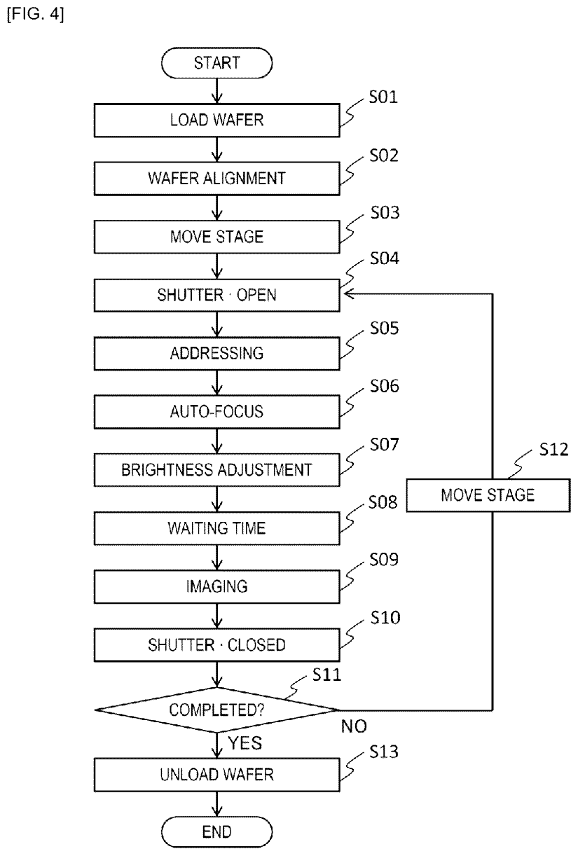

FIG. 4 shows a flow in which the SEM 100 shown in FIG. 1 acquires the SEM image used for measuring a pattern. Here, a case in which the L/S pattern (see FIG. 3) on the wafer 300 is measured will be described as an example. The flow is started by setting a measurement recipe corresponding to the measurement in the controller 112. A measurement procedure and contents are defined in advance in the measurement recipe, and the controller 112 controls the imaging unit 101 and the irradiation optical system 120 according to the measurement recipe.

First, the wafer 300 is placed on the stage 110 of the SEM 100 (S01), and the wafer 300 is aligned in two steps of an optical microscope (not shown) and an SEM image using alignment points in the wafer 300 (S02). Accordingly, coordinates defined on the wafer 300 can be recognized by the SEM 100.

After the controller 112 moves the stage 110 toward the measurement point (S03), the controller 112 opens the shutter 122 of the irradiation optical system 120 to start irradiation of the sample 109 with light (S04). A timing of starting the light irradiation is determined according to the definition of the measurement recipe. This timing is an example, and it is also possible to set the timing of starting the light irradiation to a different timing in the measurement recipe.

Next, the controller 112 moves a field of view of the imaging unit 101 to the measurement point (S05: addressing). For the addressing, the controller 112 holds addressing control data that defines in advance a specific pattern on a sample and a positional relationship between the specific pattern and the measurement point. In step S05, pattern matching is performed to search for a specific pattern, and the field of view is moved from the specific pattern toward the measurement point. The movement of the field of view is performed by the image shift deflector 106a.

Next, the controller 112 controls the objective lens 107 such that an electron beam is focused on a wafer surface at the measurement point (S06: auto-focusing). In step S06, for example, the SEM images are acquired while changing an excitation intensity of the objective lens 107, and it is determined that the electron beam is focused on the wafer surface at the excitation intensity that results in the most clear SEM image, and the excitation intensity of the objective lens 107 is set to the excitation intensity at that time.

Next, the controller 112 adjusts a gain and an offset of the detector 108 in order to adjust brightness of the SEM image obtained by the image processing unit 111 (S07: brightness adjustment).

After step S07 is completed and a predetermined waiting time elapses (S08), the controller 112 acquires the SEM image (S09). For example, an operation of scanning the electron beam by the scanning deflector 106b at the measurement point is repeatedly performed, and the SEM image is acquired by integrating frame images obtained by one scan. Thereafter, the shutter 122 is closed to complete the light irradiation to the wafer 300 (S10). The waiting time in step S08 is a step for performing time adjustment such that the irradiation amount of light from the laser light source 121 is equal at a plurality of measurement points, and a method for applying the waiting time will be described later.

When the acquisition of the SEM image for all the measurement points on the wafer 300 is not completed (NO in S11), the stage 110 is moved toward the next measurement point (S12), and processing from step S04 onwards is executed to acquire the SEM image at the next measurement point. On the other hand, when the SEM images for all the measurement points on the wafer 300 are acquired (YES in S11), the wafer 300 is taken out from the stage 110 of the SEM 100 (S13).

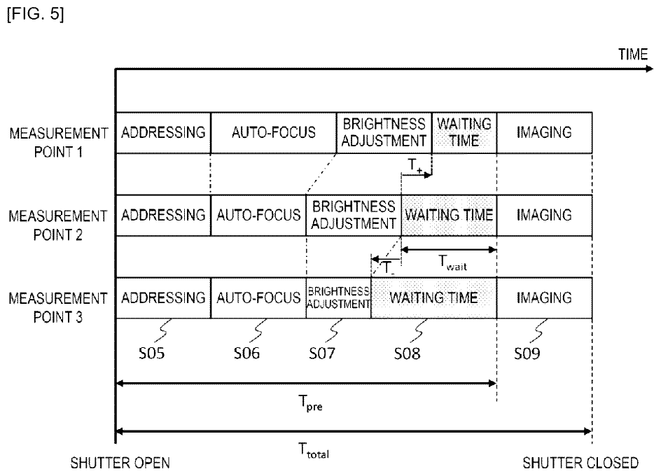

FIG. 5 shows a time chart (schematic diagram) for acquiring the SEM image at any measurement point. Specifically, FIG. 5 is a time chart of a period from the opening of the shutter 122 to the closing thereof, and the controller 112 executes steps S05 to S09. A horizontal axis represents time, and indicates an example of a time chart at three measurement points (measurement points 1 to 3). For simplification of description, a time required for the addressing (S05) and the imaging (S09) is the same for the three measurement points, a time required for the auto-focus (S06) is the same for the measurement point 2 and the measurement point 3, and is longer than that for the measurement point 1 by a time T₊, and a time required for the brightness adjustment (S07) is the same for the measurement point 1 and the measurement point 2, and is shorter than that for the measurement point 3 by a time T₋.

At this time, if the waiting time at measurement point 2 is T_{wait} using the time chart of the measurement point 2 as a reference, the controller 112 sets the waiting time on the time chart of measurement point 1 to be (T_{wait}−T₊), and the waiting time on the time chart of the measurement point 3 to be (T_{wait}+T₋). As a result, a time variation of each processing before the imaging (S09) can be offset by the waiting time, and a light irradiation time until the imaging starts at all measurement points can be aligned to Tₚᵣₑ. Accordingly, at the measurement points 1 to 3, it is also possible to control the light irradiation amount at the time of starting the imaging (S09) to be constant.

In contrast to this, if the waiting time (S08) is not set, in the example of FIG. 5, the imaging (S09) at the measurement point 1 is started after the light is emitted for a period of time longer than that of the measurement point 2 by T₊, and the imaging (S09) at the measurement point 3 is started after the light is emitted for a period of time shorter than that of the measurement point 2 by T₋, resulting in a magnitude of an effect of light irradiation differing for each measurement point. Therefore, in addition to process variation information that is originally desired to be measured, a measurement value includes variation information of the effect of light irradiation that is different for each measurement point. In the embodiment, the process variation can be detected with higher accuracy by reducing the variation in the effect of light irradiation for each measurement point.

The controller 112 may set the waiting time at each measurement point based on the light amount actually measured by the light amount monitor 125 and output from the laser light source 121. That is, in the measurement recipe, in a light irradiation time Tₜₒₜₐₗ (see FIG. 5) at each inspection point, a length of the waiting time (S08) is set such that the irradiation amount of light from the laser light source 121 monitored by the light amount monitor 125 is equal. For example, in the measurement recipe, a predetermined amount of power is defined as the irradiation amount of light from the laser light source 121 in the light irradiation time Tₜₒₜₐₗ, and the controller 112 starts the imaging (S09) when the power monitored by the light amount monitor 125 is accumulated and reaches the predetermined amount of power. In this way, compared to a case in which the length of the waiting time is defined by time under an assumption that the output of the laser light source 121 is constant, the method enables reduction in the effect of temporal jitter in the light amount of output by the laser light source 121 and more accurate reduction in the variation in the effect of light irradiation at each inspection point.

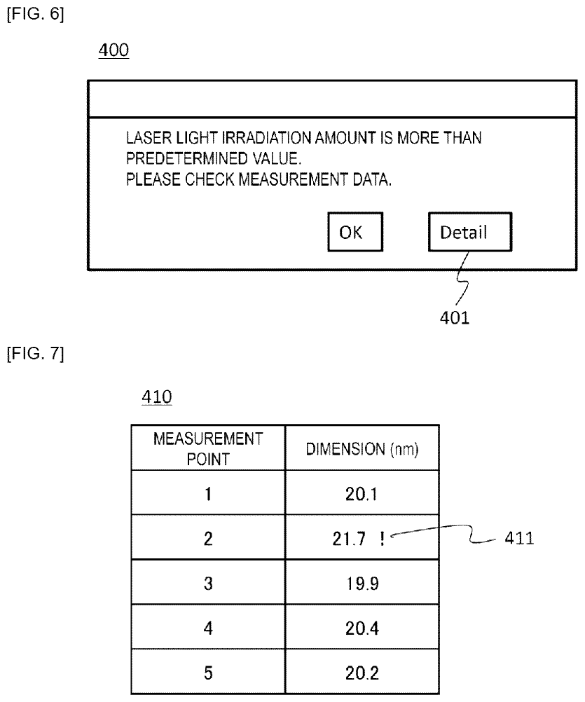

In the configuration of FIG. 1, since the controller 112 can monitor the light irradiation amount with which the measurement point is irradiated, the light irradiation amount with which the measurement point is irradiated can be stored as additional information of a measurement result, and can be utilized as information indicating reliability of the measurement result. For example, when the light irradiation amount at the measurement point is more than a predetermined amount, an alarm screen as shown in FIG. 6 can be displayed. When the user presses a detail button 401 of an alarm screen 400, measurement result data shown in FIG. 7 is displayed. Dimensions measured for each measurement point are displayed, and an alarm mark 411 indicating that the light irradiation amount is more than the predetermined amount is added to a measurement result of the measurement point 2. Accordingly, the user can recognize that the measurement value includes the effect of light irradiation.

### Embodiment 2

In Embodiment 2, creation of a measurement recipe for performing the measurement described in Embodiment 1 will be described. Here, an example in which the controller 112 creates the measurement recipe will be described, but the measurement recipe may be created using an information processing device different from the controller 112.

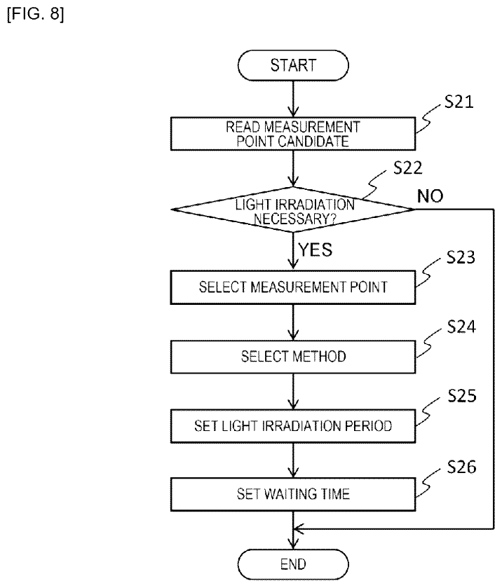

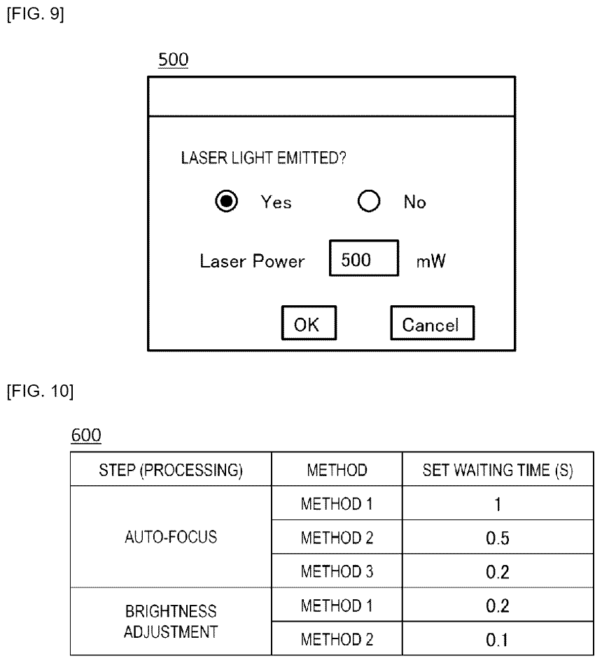

FIG. 8 shows a flow of creating the measurement recipe. However, the flow is obtained by extracting a portion related to a light irradiation timing setting method for acquiring an SEM image. First, a measurement point candidate is read (S21). The measurement point candidate is created based on, for example, CAD data of the wafer 300. Next, whether light irradiation by the irradiation optical system 120 is necessary is checked (S22). FIG. 9 shows an example of a checking screen 500. If the light irradiation is necessary, output power of the laser light source 121 to be used is also set. If the light irradiation is not necessary, the flow ends.

Next, a measurement point to be actually measured is selected from the measurement point candidate (S23). In the selection, since a spot diameter of the light from the irradiation optical system 120 has a size that can include a plurality of measurement point candidates, a selection condition is that the measurement point is not irradiated with light a plurality of times in an overlapped manner. Presence or absence of the overlap can be determined based on the coordinates of each measurement point candidate and the size of the spot diameter of light.

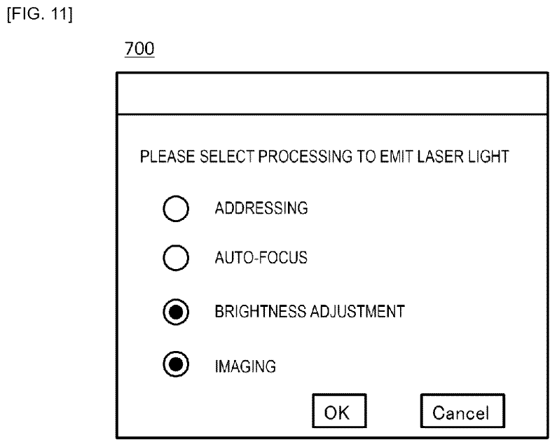

Next, a processing method is selected for a plurality of methods that can be taken for processing during light irradiation (S24). In Embodiment 1, a specific processing method is exemplified for the steps S05 to S07 performed during the light irradiation, but there are steps in which the processing method can be selected in addition to the content of the example, and in this case, the time variation which may occur in the steps may be different depending on the processing method. FIG. 10 is an example of a processing method database stored in the controller 112 for appropriately setting the waiting time when the processing method is selected. In a processing method database 600, possible methods for each processing and a waiting time in that case are registered. Here, the waiting time is calculated as a variation in a processing time required when the method is adopted in the step.

Next, a period for performing light irradiation is set (S25). FIG. 11 shows an example of a selection screen 700. Embodiment 1 corresponds to a flow executed when all steps (processing) displayed on the selection screen 700 are selected. On the other hand, when it is desired to shorten the light irradiation period as much as possible, it is possible to reduce the effect of light irradiation while reducing the variation in the effect of light irradiation by excluding a specific step from the period in which light irradiation is performed. For example, in the example of FIG. 11, since the brightness adjustment (S07) and the imaging (S09) are set as the light irradiation period, the time variation of the brightness adjustment (S07) is absorbed by the waiting time, and since the light irradiation is not performed in the addressing (S05) and the auto-focus (S06), the light irradiation period is shortened, and since the time variation required to be absorbed is only the time variation in the brightness adjustment (S07), the length of the waiting time (S08) can be shortened.

Next, the length of the waiting time is set (S26). The waiting time is set based on the light irradiation period set in step S25 and the processing method selected in step S24. When the waiting time is the irradiation amount of light from the laser light source 121, a product of a sum of the waiting times defined in the processing method database 600 and the output power of the laser light source 121 entered on the checking screen 500 for the steps included in the light irradiation period may be set as a target value of the irradiation amount of light.

The invention is not limited to the embodiments described above and includes various modifications. For example, the embodiments are described in detail for easy understanding of the present disclosure, and are not necessarily limited to those having all the configurations described above. A part of the configuration of one embodiment and modification can be replaced with the configuration of another embodiment and modification, and the configuration of another embodiment and modification can be added to the configuration of one embodiment and modification. A part of a configuration in each of the embodiments and the modification may be added to, deleted from, or replaced with another configuration.

### REFERENCE SIGNS LIST

100: scanning electron microscope
101: imaging unit
102: electron source
103, 105: focusing lens
104: diaphragm
106a: image shift deflector
106b: scanning deflector
107: objective lens
108: detector
109: sample
110: stage
111: image processing unit
112: controller
120: irradiation optical system
121: laser light source
122: shutter
123: mirror
124: half mirror
125: light amount monitor
200: information processing device
201: processor (CPU)
202: memory
203: storage device
204: input I/F
205: output I/F
206: communication I/F
207: bus
300: wafer
301: chip region
302, 303: measurement point
311: resist
312: conductive layer
400: alarm screen
401: detail button
411: alarm mark
500: checking screen
600: processing method database
700: selection screen

1. A measurement device for measuring a dimension of a predetermined pattern on a wafer at a plurality of measurement points, the measurement device comprising:
an imaging unit including a charged particle optical system, a stage, and a detector configured to detect signal electrons emitted when the wafer placed on the stage is irradiated with a charged particle beam from the charged particle optical system;
an image processing unit configured to generate a scanning image in response to a detection signal output by the detector after the charged particle optical system scans the wafer with the charged particle beam and the detector detects the signal electrons;
an irradiation optical system including a laser light source, an optical element configured to irradiate a region including a field of view of the charged particle optical system with light from the laser light source, and a shutter configured to control irradiation toward the region with the light from the laser light source; and
a controller configured to control the imaging unit and the irradiation optical system, wherein
the controller performs time adjustment such that an irradiation amount of light from the laser light source from when the shutter is opened to start the irradiation with the light from the laser light source to when the imaging unit starts imaging of the scanning image is equal at the plurality of measurement points.

2. The measurement device according to claim 1, wherein
the controller closes the shutter and completes the irradiation with the light from the laser light source when imaging of the scanning image is completed.

3. The measurement device according to claim 2, wherein
the irradiation optical system includes a light amount monitor configured to monitor a light amount from the laser light source, and
the controller performs the time adjustment such that the irradiation amount of light from the laser light source monitored by the light amount monitor during a period when the shutter is opened is equal at the plurality of measurement points.

4. The measurement device according to claim 3, wherein
the controller displays an alarm when the irradiation amount of light from the laser light source monitored by the light amount monitor during the period when the shutter is opened is more than a predetermined value.

5. The measurement device according to claim 1, wherein
the irradiation optical system includes a light amount monitor configured to monitor a light amount from the laser light source, and
the controller performs the time adjustment according to a measurement recipe set according to measurement at the plurality of measurement points such that the irradiation amount of light from the laser light source monitored by the light amount monitor during a period when the shutter is opened is equal at the plurality of measurement points.

6. A measurement device for measuring a dimension of a predetermined pattern on a wafer at a plurality of measurement points, the measurement device comprising:
an imaging unit including a charged particle optical system, a stage, and a detector configured to detect signal electrons emitted when the wafer placed on the stage is irradiated with a charged particle beam from the charged particle optical system;
an image processing unit configured to generate a scanning image in response to a detection signal output by the detector after the charged particle optical system scans the wafer with the charged particle beam and the detector detects the signal electrons;
an irradiation optical system including a laser light source, an optical element configured to irradiate a region including a field of view of the charged particle optical system with light from the laser light source, and a shutter configured to control irradiation toward the region with the light from the laser light source; and
a controller configured to create a measurement recipe that defines a procedure and a content of measurement at the plurality of measurement points, wherein
the controller defines, in the measurement recipe, a procedure for performing time adjustment such that an irradiation amount of light from the laser light source from when the shutter is opened to start the irradiation with the light from the laser light source to when the imaging unit starts imaging of the scanning image is equal at the plurality of measurement points.

7. The measurement device according to claim 6, wherein
the irradiation optical system includes a light amount monitor configured to monitor a light amount from the laser light source, and
the controller defines, in the measurement recipe, the procedure for performing the time adjustment such that the irradiation amount of light from the laser light source monitored by the light amount monitor during a period when the shutter is opened is equal at the plurality of measurement points.

8. The measurement device according to claim 6, wherein
the controller selects from a plurality of measurement point candidates such that the light from the laser light source is not emitted in an overlapped manner, and defines the plurality of measurement points in the measurement recipe.

9. The measurement device according to claim 6, wherein
the controller is allowed to set, in the measurement recipe, different lengths of waiting times for the time adjustment according to a type of processing executed by the imaging unit while the shutter is open.

10. The measurement device according to claim 6, wherein
the controller defines, in the measurement recipe, a timing at which the shutter is to be opened to start which processing to be executed by the imaging unit.

11. The measurement device according to claim 6, wherein
the controller controls the imaging unit and the irradiation optical system according to the measurement recipe.

12. A scanning image acquisition method for a measurement device that measures a dimension of a predetermined pattern on a wafer at a plurality of measurement points,
the measurement device including an imaging unit including a charged particle optical system, a stage, and a detector configured to detect signal electrons emitted when the wafer placed on the stage is irradiated with a charged particle beam from the charged particle optical system, an image processing unit configured to generate a scanning image in response to a detection signal output by the detector after the charged particle optical system scans the wafer with the charged particle beam and the detector detects the signal electrons, an irradiation optical system including a laser light source, an optical element configured to irradiate a region including a field of view of the charged particle optical system with light from the laser light source, and a shutter configured to control irradiation toward the region with the light from the laser light source, and a controller configured to control the imaging unit and the irradiation optical system,
the scanning image acquisition method comprising:
opening, by the controller, the shutter to start irradiation with light from the laser light source; and
performing, by the controller, time adjustment such that an irradiation amount of light from the laser light source from the start of the irradiation with the light from the laser light source to the start of imaging of the scanning image by the imaging unit is equal at the plurality of measurement points, and then starting the imaging of the scanning image.

13. The scanning image acquisition method according to claim 12, wherein
the controller closes the shutter and completes the irradiation with the light from the laser light source when the imaging of the scanning image is completed.

14. The scanning image acquisition method according to claim 13, wherein
the irradiation optical system includes a light amount monitor configured to monitor a light amount from the laser light source, and
the controller performs the time adjustment such that the irradiation amount of light from the laser light source monitored by the light amount monitor during a period when the shutter is opened is equal at the plurality of measurement points.

15. The scanning image acquisition method according to claim 14, wherein
the controller displays an alarm when the irradiation amount of light from the laser light source monitored by the light amount monitor during the period when the shutter is opened is more than a predetermined value.
